(19) United States
(12) Patent Application Publication
(10) Pub. No.: US 2008/0048259 A1
(43) Pub. Date: Feb. 28, 2008

(54) Method for Reducing Defects in Buried Oxide Layers of Silicon on Insulator Substrates

(76) Inventors: Kangguo Cheng, Beacon, NY (US); Ramachandra Divakaruni, Ossining, NY (US); Louis Lu-Chen Hsu, Fishkill, NY (US); Jack Allan Mandelman, Flat Rock, NC (US)

Correspondence Address: SCHMEISER, OLSEN & WATTS, 22 CENTURY HILL DRIVE, SUITE 302, LATHAM, NY, 12110, US

(21) Appl. No.: 11/466,480

(22) Filed: Aug. 23, 2006

(51) Int. Cl. H01L 27/12

(52) U.S. Cl. 257/347

(57) ABSTRACT

A method and a structure for reducing defects in buried oxide layers of a silicon-on-insulator substrate. The method includes: generating a beam of infrared radiation of a selected wavelength; exposing a silicon-on-insulator substrate to the beam of infrared radiation, the substrate comprising a buried silicon dioxide layer between a lower layer of silicon and an upper layer of silicon; and wherein silicon has a transmittance of at least 95% at the selected wavelength and silicon dioxide has a transmittance of less than 80% at the selected wavelength.

### FIELD OF THE INVENTION

The present invention relates to the field of semiconductor technology; more specifically, it relates to a method to reduce defects in buried oxide layers of silicon-on-insulator semiconductor substrates.

### BACKGROUND OF THE INVENTION

Silicon-on-insulator (SOI) technology has been widely adapted for advanced CMOS device scaling and performance enhancement. Fabricating CMOS devices on an SOI substrate has advantages such as low junction capacitance, high device performance and low power consumption. However, defects are inevitably introduced into the insulator layer, often referred to as a buried oxide layer or BOX layer. An exemplary process introducing defects into the BOX layer is ion implantation. Ions scattering into the BOX, as a by-product of ion implantation for device doping is responsible for the introduction of defects such as carrier traps and fixed charge into the BOX.

These defects in the BOX can negatively impact device performance. For example, carrier traps in the BOX can result in backside leakage currents. Therefore, there is a need for a method to reduce defects in BOX layers during fabrication of integrated circuits.

### SUMMARY OF THE INVENTION

A first aspect of the present invention is a method, comprising: generating a beam of infrared radiation of a selected wavelength; exposing a silicon-on-insulator substrate to the beam of infrared radiation, the substrate comprising a buried silicon dioxide layer between a lower layer of silicon and an upper layer of silicon; and wherein silicon has a transmittance of at least 95% at the selected wavelength and silicon dioxide has a transmittance of less than 80% at the selected wavelength.

A second aspect of the present invention is a structure, comprising: a buried silicon dioxide layer between a lower layer of silicon and an upper layer of silicon; and an infrared absorption layer that absorbs infrared radiation within the silicon dioxide layer.

### BRIEF DESCRIPTION OF DRAWINGS

The features of the invention are set forth in the appended claims. The invention itself, however, will be best understood by reference to the following detailed description of an illustrative embodiment when read in conjunction with the accompanying drawings, wherein:

FIGS. 1A and 1B are cross-sectional drawings of the fabrication of an integrated circuit illustrating a method for reducing defects in BOX layer of SOI substrates according to a first embodiment of the present invention;

FIGS. 2A though 2C are cross-sectional drawings of the fabrication of an integrated circuit illustrating a method for reducing defects in BOX layer of SOI substrates according to a second embodiment of the present invention;

FIGS. 3A though 3C are cross-sectional drawings of the fabrication of an integrated circuit illustrating a method for reducing defects in BOX layer of SOI substrates according to a third embodiment of the present invention;

FIGS. 4A though 4D are cross-sectional drawings of the fabrication of an integrated circuit illustrating a method for reducing defects in BOX layer of SOI substrates according to a fourth embodiment of the present invention;

FIG. 5 is a cross-sectional drawing of an integrated circuit illustrating a method for reducing defects in BOX layer of SOI substrates according to a fifth embodiment of the present invention;

FIG. 6 is a cross-sectional drawing of an integrated circuit illustrating a method for reducing defects in BOX layer of SOI substrates according to a sixth embodiment of the present invention

FIG. 7 is a cross-sectional drawing of an integrated circuit illustrating a method for reducing defects in BOX layer of SOI substrates according to a seventh embodiment of the present invention;

FIG. 8 is a cross-sectional drawing of an integrated circuit illustrating a method for reducing defects in BOX layer of SOI substrates according to an eighth embodiment of the present invention.

### DETAILED DESCRIPTION OF THE INVENTION

When infrared (IR) radiation is incident on a silicon layer, depending on the wavelength of the radiation, some of the energy is reflected from the surface of the silicon layer, some of the energy is transmitted through the silicon layer and some of the energy is absorbed by the silicon layer. In one study using a single-crystal silicon wafer having a thickness of about 600 microns, it was found that there was no significant absorption of IR having a wavelength below about 6500 nm and 55% of the energy was transmitted through the wafer with about 45% reflected at the incident surface.

The IR transmission spectra of fused silica (SiO₂) shows virtually 0% transmittance of IR radiation between about 2700 nm and about 2900 nm and no more than about 80% transmittance between about 2500 nm and about 3400 nm. From about 3400 nm to about 4300 nm the transmittance steeply decreases from about 80% to about 0%. At about 1400 nm there is a dip to about 78% transmittance and at about 1950 nm there is a dip to about 52% transmittance. From about 3000 nm there is a precipitous drop to about 0% transmittance. Therefore, there exist IR wavelengths that will penetrate through silicon but be absorbed by a SiO₂ layer buried in the silicon. The embodiments of the present invention utilize wavelengths of IR radiation to which silicon is essentially transparent and which are absorbed by silicon dioxide. In one example, silicon has a transmittance of at least 95% at a selected IR wavelength and silicon dioxide has a transmittance of less than 80% at the selected IR wavelength.

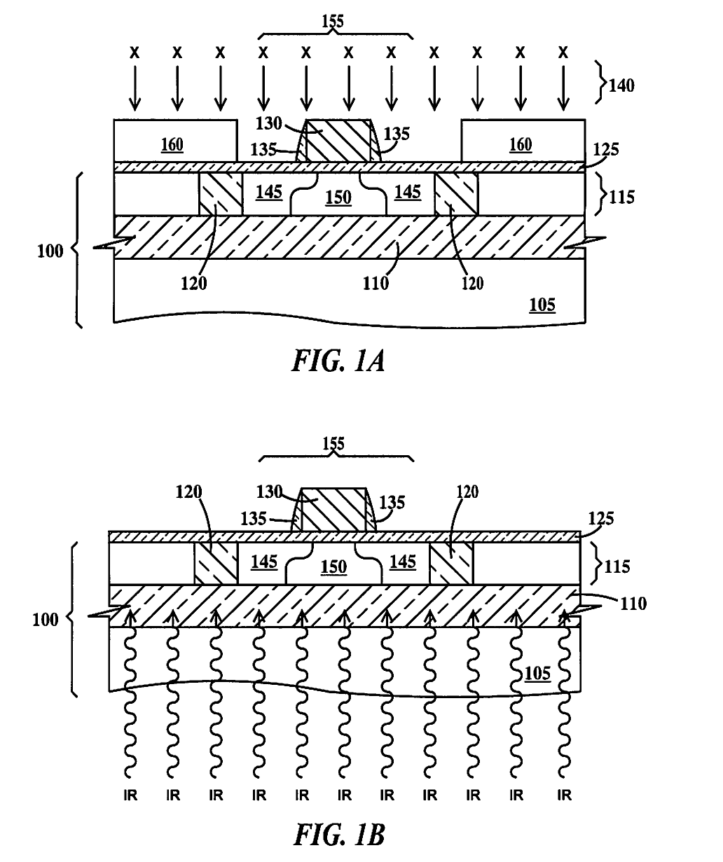

FIGS. 1A and 1B are cross-sectional drawings of the fabrication of an integrated circuit illustrating a method for reducing defects in BOX layer of SOI substrates according to a first embodiment of the present invention. In FIG. 1A, an SOI substrate 100 includes a lower silicon layer 105, a BOX layer 110 of SiO₂ between the lower silicon layer 105 and an upper silicon layer 115. In one example, both lower and upper silicon layers 105 and 115 comprise single-crystal silicon. In one example, substrate 105 is between about 200 to 1000 microns thick. In one example, BOX layer 110 is between about 50 nm and about 200 nm thick. In one example, upper silicon layer 115 is between about 5 nm and about 100 nm thick.

Typically, during fabrication of integrated circuits, active circuit devices are formed in regions of upper silicon layer 115 which are separated by shallow trench isolation (STI) 120. In one example, STI 120 comprises SiO₂. In one example, a gate dielectric layer 125 is formed on a top surface of upper silicon layer 115, an electrically conductive gate electrode 130 is formed on the gate dielectric layer and over upper silicon layer 115 and dielectric spacers formed on the sidewalls of the gate electrode. In an ion implantation step, an ion beam 140 of dopant species ions is directed to the top surface of SOI substrate 100 to form source/drain regions 145 and channel region 150 of a field effect transistor (FET) 155. Gate electrode 130, which is part of FET 155 blocks ion beam 140 from penetrating into underlying upper silicon layer 115. An optional photoresist layer 160 may be formed on top of gate dielectric layer 125 to block the ion implantation in other regions of the upper silicon layer.

However, ions from ion beam 140 will scatter into BOX layer 110 under source/drain regions 145 creating defects such as carrier traps and fixed charge in the BOX layer. Consequences of the carrier traps and fixed charge induced in BOX layer 110 on an FET formed in the BOX layer include increased drain diffusion to body leakage and backside channel leakage. Accentuated drain to body leakage is of particular concern for SOI MOSFET designs having source-drain diffusions, or portions thereof, which do not fully extend to the BOX, as the junction depletion region is exposed to the induced defects. Drain to body leakage still of concern, though to a lesser extent, for designs where the source-drain diffusions extend all the way to the BOX. Increased drain to body leakage may result in increased FET body charging and SOI history effect. Backside leakage is particularly troublesome for fully depleted FETs, but is also a concern for partially depleted SOI MOSFETs.

It should be understood that the formation of FET 155 is exemplary and illustrates damage created in a BOX layer of an SOI substrate by an ion implantation step during fabrication of an integrated circuit. Other devices that are fabricated using ion implantation steps include, but are not limited to bipolar transistors, diodes, capacitors and resistors. It should further be understood that, besides ion implantation, other processes, e.g., reactive ion etching, can also create defects in a BOX layer of an SOI substrate.

In FIG. 1B, IR radiation is directed from the bottom surface of SOI substrate 100 through lower silicon layer 105 into BOX layer 110 where the IR energy is absorbed. The wavelength of the IR radiation is chosen such that it passes through lower silicon layer 105 and is absorbed by BOX layer 110, causing BOX layer 110 to heat up and anneal out a significant number of the defects introduced into the BOX layer by ion implantation steps during fabrication of an integrated circuit. Some defects introduced into BOX layer 110, by means other than ion-implantation, will also be annealed away.

In one example, the IR radiation has a wavelength of between about 1000 nm and about 20,000 nm. In one example, IR radiation has a wavelength of between about 2700 nm and about 2900 nm. In one example, the energy density of IR radiation impinging on the bottom surface of SOI substrate 100 is between about 0.001 mJ/cm² and about 2 mJ/cm². In one example the time duration of the backside exposure of IR radiation is between about 1 femto-second and about 10 seconds. The IR radiation may be pulsed on and off to maintain BOX layer 110 at a selected temperature for a selected amount of time. In one example, BOX layer 110 reaches a maximum temperature of between about 200° C. and about 1200° C. In one example, BOX layer 110 reaches a maximum temperature of between about 300° C. and about 800° C. In one example, BOX layer 110 reaches a maximum temperature of between about 400° C. and about 550° C.

Suitable sources for the IR radiation of the specified wavelengths include Li⁺:Na⁺ doped KCl or RbCl wavelength tunable lasers. Other methods for selecting IR radiation of a particular wavelength include passing IR radiation from a broadband IR source through a grating or prism. For example, a grating of 300 to 600 grooves/mm may be used to select wavelengths between 800 nm and 2500 nm, while a grating of 100 to 300 grooves/mm may be used to select wavelengths between 2500 nm and 5000 nm. For example, a prism comprised of SiO₂ may be used to select wavelengths between 250 nm and 2000 nm, a prism comprised of LiF may be used to select wavelengths between 250 nm and 5000 nm, a prism comprised of CaF₂ may be used to select wavelengths between 200 nm and 9000 nm, a prism comprised of BaF₂ may be used to select wavelengths between 200 nm and 13,000 nm, a prism comprised of NaCl may be used to select wavelengths between 2000 nm and 16,000 nm, and a prism comprised of KBr may be used to select wavelengths between 10,000 nm and 20,000 nm.

In one example, the IR radiation step is performed after fabrication of the devices is complete, but before fabrication of the wiring levels of the integrated circuit chip. In one example, the IR radiation step is performed after fabrication of at least the first wiring level of the integrated circuit chip.

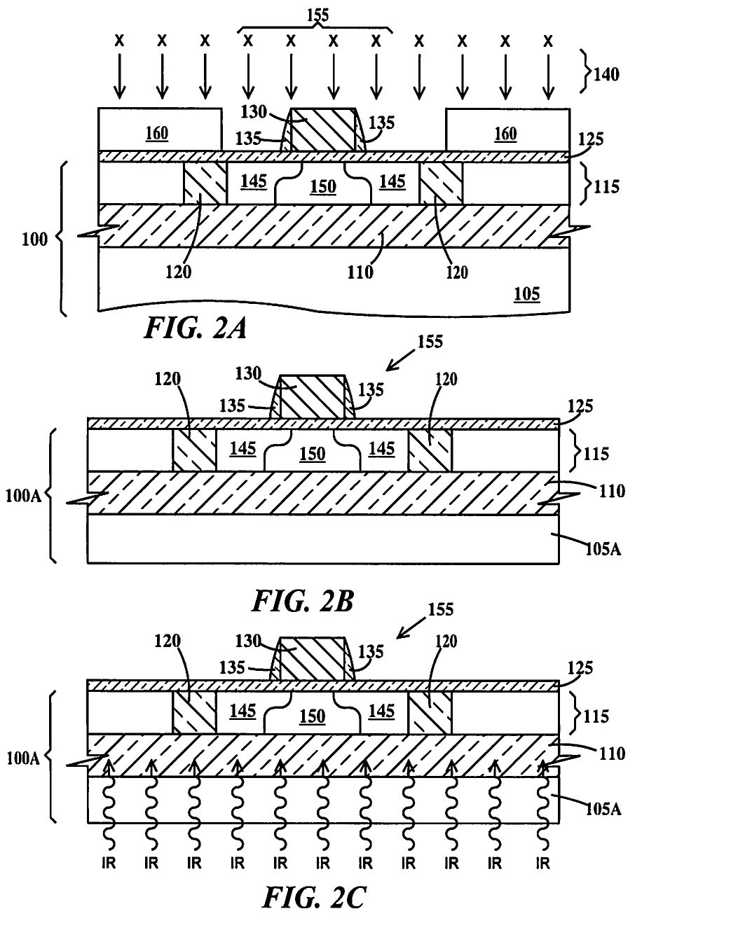

FIGS. 2A though 2C are cross-sectional drawings of the fabrication of an integrated circuit illustrating a method for reducing defects in BOX layer of SOI substrates according to a second embodiment of the present invention. FIG. 2A is the same as FIG. 1A. In FIG. 2B, lower silicon layer 105 of FIG. 2A has been thinned to form a thinned lower silicon layer 105A of a thinned SOI substrate 100A. The thinning may be accomplished by grinding, chemical-mechanical-polishing, chemical etching or combinations thereof. In one example, lower silicon layer 105A is between about 30 microns and about 300 microns thick. FIG. 2C is similar to FIG. 1B except the IR radiation is directed from the bottom surface of SOI substrate 100A through lower silicon layer 105A into BOX layer 110.

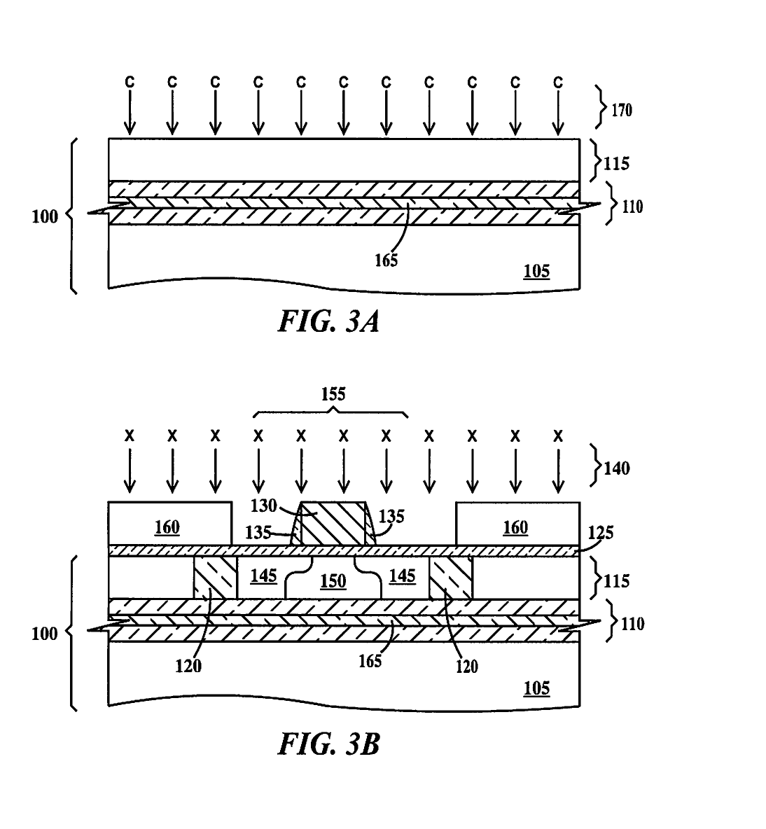

FIGS. 3A though 3C are cross-sectional drawings of the fabrication of an integrated circuit illustrating a method for reducing defects in BOX layer of SOI substrates according to a third embodiment of the present invention. In FIG. 3A, prior to any fabrication steps of integrated circuit chips, an IR absorption layer 165 is formed in BOX layer 110. In one example, IR absorption layer 165 is formed by exposure of SOI substrate to an ion beam 170 of carbon species ions. A high temperature anneal (greater than about 500° C.) after implantation of the carbon is optional. Also the implantation may be made through an optional sacrificial layer (not shown) that protects the surface of upper silicon layer 115 from damage and is then removed. Though illustrated as being centered within BOX layer 110, IR absorption layer 165 may be located anywhere within the BOX layer.

Except for the presence of IR absorption layer 165, FIG. 3B is similar to FIG. 1A and FIG. 3B is similar to FIG. 1B. In FIG. 3C absorption of the IR energy in BOX layer 110 is enhanced by the presence of IR absorption layer 165.

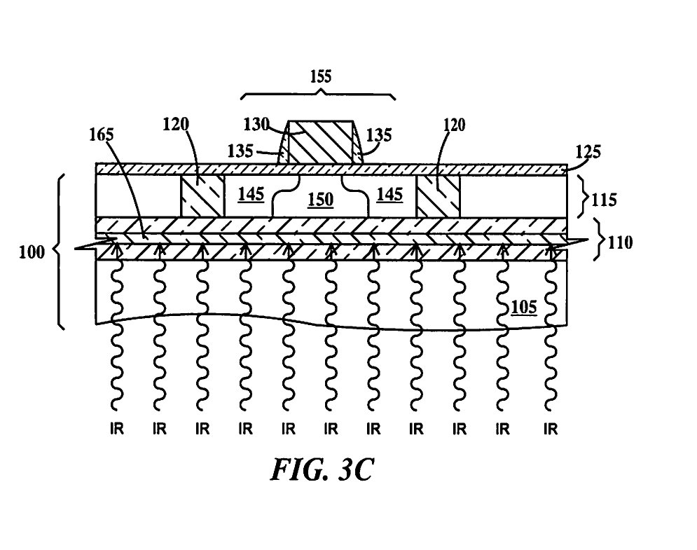

FIGS. 4A though 4D are cross-sectional drawings of the fabrication of an integrated circuit illustrating a method for reducing defects in BOX layer of SOI substrates according to a fourth embodiment of the present invention. The fourth embodiment of the present invention combines the second and third embodiments. FIG. 4A is the same as FIG. 3A. FIG. 4B is the same as FIG. 3B. In FIG. 4C, lower silicon layer 105 of FIG. 2A has been thinned to form a thinned lower silicon layer 105A of a thinned SOI substrate 100A as described supra. In FIG. 4D, IR radiation is directed from the bottom surface of SOI substrate 100A through lower silicon layer 105A into BOX layer 110 where absorption of the IR energy is enhanced by IR absorption layer 165.

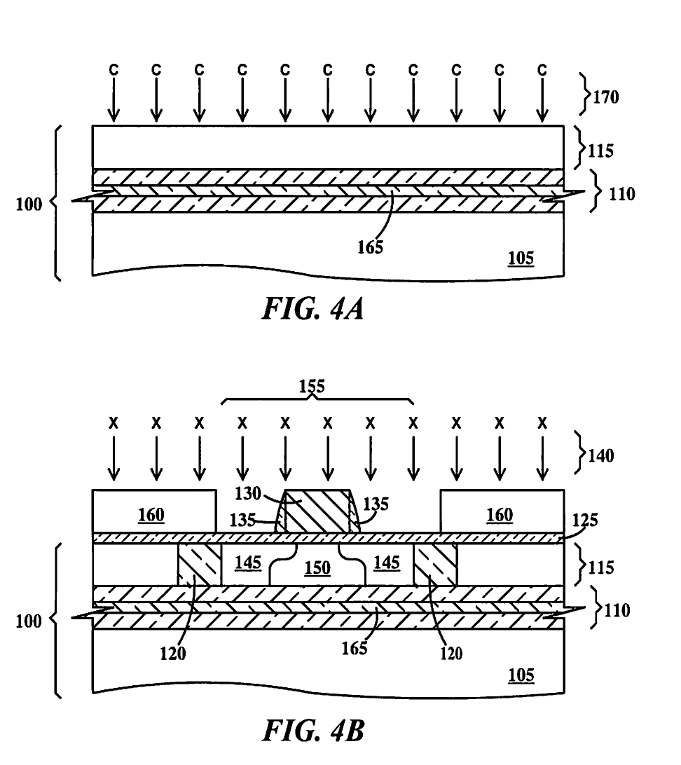

FIG. 5 is a cross-sectional drawing of an integrated circuit illustrating a method for reducing defects in the BOX layer of SOI substrates according to a fifth embodiment of the present invention. In FIG. 5, prior to backside IR irradiation, fabrication of devices (such as transistors, diodes and resistors) has been completed in regions 175A and 175B of upper silicon layer 115 and a temperature sensor has been formed in a region 180 of the upper silicon layer. The temperature sensor may be a resistor, diode or transistor. One or more optional wiring levels 185 may be formed to combine the temperature sensor and other devices into a temperature sense circuit. Then, IR radiation is directed from the bottom surface of SOI substrate 100 through lower silicon layer 105 into BOX layer 110 where the IR energy is absorbed. The wavelength of the IR radiation is chosen such that it passes through lower silicon layer 105 and is absorbed by BOX layer 110, causing BOX layer 110 to heat up. The temperature sensor measures the temperature of BOX layer 110 and can be used to generate a signal to turn off the IR source after a selected temperature is reached or after the BOX layer has been at a selected temperature for a selected duration of time.

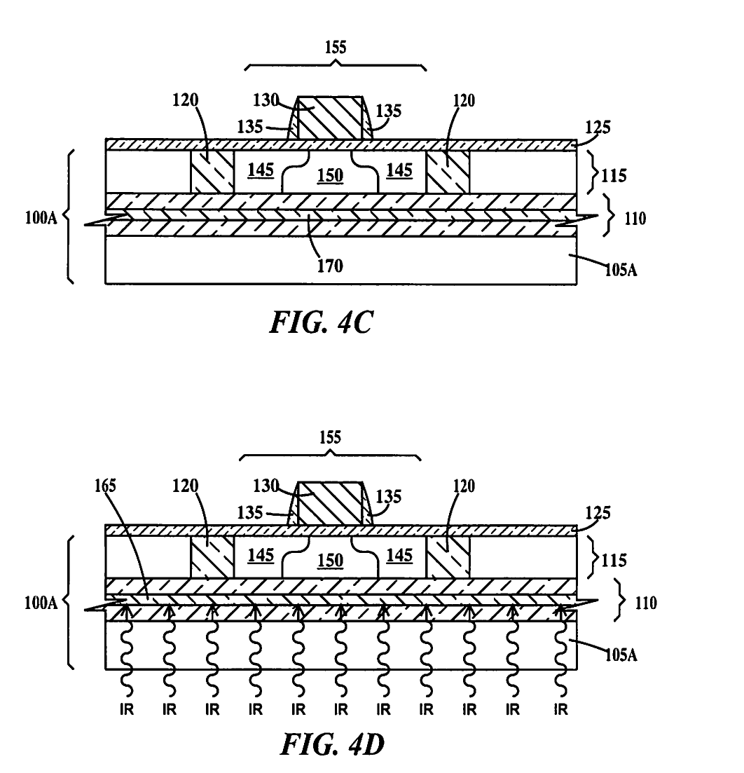

FIG. 6 is a cross-sectional drawing of an integrated circuit illustrating a method for reducing defects in BOX layer of SOI substrates according to a sixth embodiment of the present invention. In FIG. 6, prior to backside IR irradiation, fabrication of devices (such as transistors, diodes and resistors) has been completed in regions 175A and 175B of upper silicon layer 115, a temperature sensor has been formed in a region 180 of the upper silicon layer and the SOI substrate has been thinned from the backside to form lower silicon layer 105A. The temperature sensor may be a resistor, diode or transistor. One or more optional wiring levels 185 may be formed to combine the temperature sensor and other devices into a temperature sense circuit. Then, IR radiation is directed from the bottom surface of SOI substrate 100 through lower silicon layer 105A into BOX layer 110 where the IR energy is absorbed. The wavelength of the IR radiation is chosen such that it passes through lower silicon layer 105A and is absorbed by BOX layer 110, causing BOX layer 110 to heat up. The temperature sensor measures the temperature of BOX layer 110 and can be used to generate a signal to turn off the IR source after a selected temperature is reached or maintained for a predetermined period of time in the BOX.

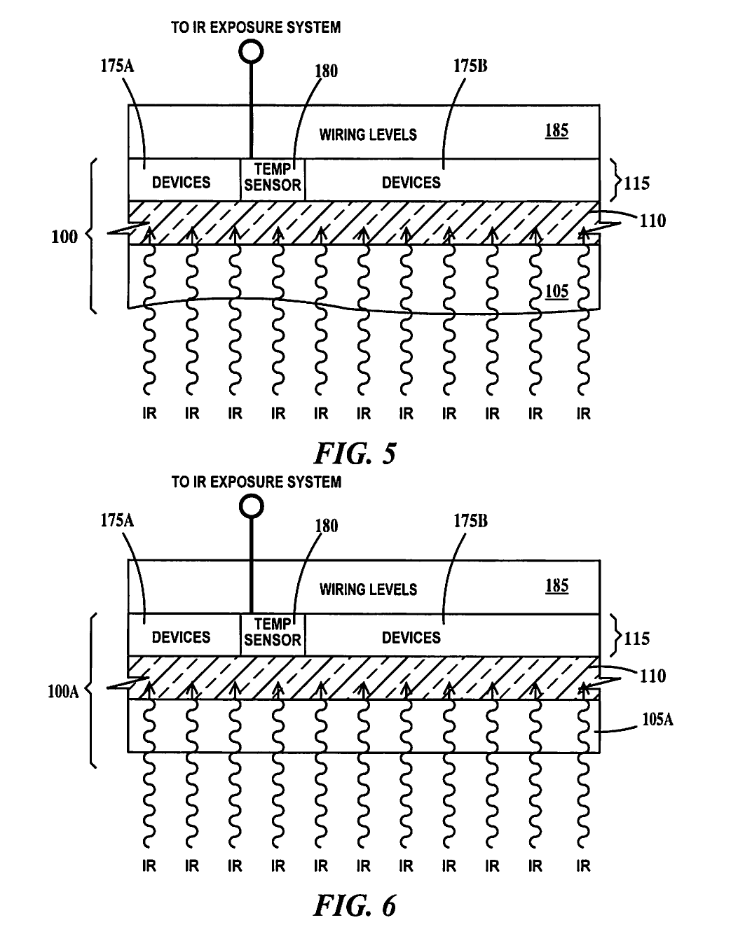

FIG. 7 is a cross-sectional drawing of an integrated circuit illustrating a method for reducing defects in BOX layer of SOI substrates according to a seventh embodiment of the present invention. In FIG. 7, prior to backside IR irradiation, IR absorption layer 165 has been formed in BOX layer 110, fabrication of devices (such as transistors, diodes and resistors) has been completed in regions 175A and 175B of upper silicon layer 115 and a temperature sensor has been formed in a region 180 of the upper silicon layer. The temperature sensor may be a resistor, diode or transistor. One or more optional wiring levels 185 may be formed to combine the temperature sensor and other devices into a temperature sense circuit. Then, IR radiation is directed from the bottom surface of SOI substrate 100 through lower silicon layer 105 into BOX layer 110 where the IR energy is absorbed. The wavelength of the IR radiation is chosen such that it passes through lower silicon layer 105 and is absorbed by BOX layer 110 and IR absorption layer 165, causing BOX layer 110 to heat up. The temperature sensor measures the temperature of BOX layer 110 and can be used to generate a signal to turn off the IR source after a selected temperature is reached or after the BOX layer has been at a selected temperature for a selected duration of time.

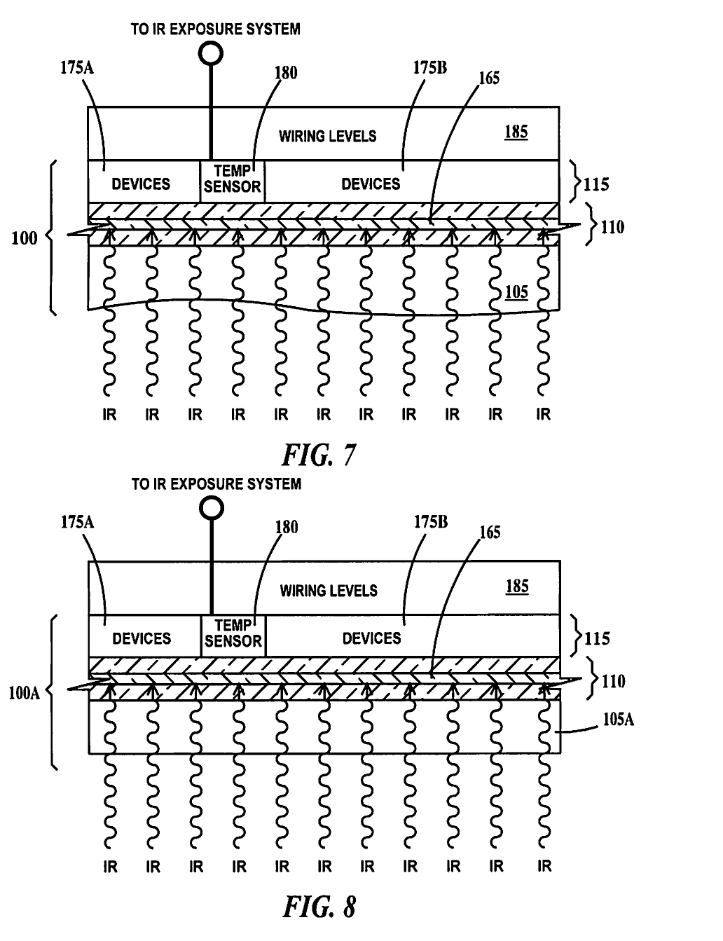

FIG. 8 is a cross-sectional drawing of an integrated circuit illustrating a method for reducing defects in BOX layer of SOI substrates according to a eighth embodiment of the present invention. In FIG. 8, prior to backside IR irradiation, IR absorption layer 165 has been formed in BOX layer 110, fabrication of devices (such as transistors, diodes and resistors) has been completed in regions 175A and 175B of upper silicon layer 115, a temperature sensor has been formed in a region 180 of the upper silicon layer, and the SOI substrate has been thinned from the backside to form lower silicon layer 105A. The temperature sensor may be a resistor, diode or transistor. One or more optional wiring levels 185 may be formed to combine the temperature sensor and other devices into a temperature sense circuit. Then, IR radiation is directed from the bottom surface of SOI substrate 100 through lower silicon layer 105A into BOX layer 110 where the IR energy is absorbed. The wavelength of the IR radiation is chosen such that it passes through lower silicon layer 105A and is absorbed by BOX layer 110 and IR absorption layer 165, causing BOX layer 110 to heat up. The temperature sensor measures the temperature of BOX layer 110 and can be used to generate a signal to turn off the IR source after a selected temperature is reached or after the BOX layer has been at a selected temperature for a selected duration of time.

Thus, the embodiments of the present invention provide methods to reduce defects in BOX layers during fabrication of integrated circuits.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. For example, SOI substrates prior to any integrated circuit fabrication steps may be exposed to IR radiation of the wavelengths and energy densities described supra from either the top surface or the bottom surface of the substrates to remove BOX defects generated during fabrication of the SOI substrate. These “unprocessed” substrates may include an IR absorption layer as described supra. Therefore it is intended that the following claims cover all such modifications and changes as fall within the true spirit and scope of the invention.

What is claimed is:

1. A method, comprising:
generating a beam of infrared radiation of a selected wavelength;
exposing a silicon-on-insulator substrate to said beam of infrared radiation, said substrate comprising a buried silicon dioxide layer between a lower layer of silicon and an upper layer of silicon; and
wherein silicon has a transmittance of at least 95% at said selected wavelength and silicon dioxide has a transmittance of less than 80% at said selected wavelength.

2. The method of claim 1, wherein said selected wavelength is between about 1000 nm and about 20,000 nm.

3. The method of claim 1, wherein said selected wavelength is between about 2700 nm and about 2900 nm.

4. The method of claim 1, wherein said beam of infrared radiation has an energy density between about 0.001 mJ/cm² and about 2 mJ/cm².

5. The method of claim 1, further including:
controlling said exposing so said silicon dioxide layer reaches a maximum temperature of between about 300° C. and about 800° C. from interaction of said infrared radiation with said buried oxide layer.

6. The method of claim 1, further including:
controlling said exposing so said silicon dioxide layer reaches a maximum temperature of between about 400° C. and about 550° C. from interaction of said infrared radiation with said buried oxide layer.

7. The method of claim 1, further including:
pulsing said beam of IR radiation off and on in order to maintain said silicon dioxide layer at a selected temperature for a selected amount of time.

8. The method of claim 1, wherein said lower silicon layer is between about 200 microns and about 1000 microns thick.

9. The method of claim 1, further including:
prior to said exposing, forming an infrared absorption layer that absorbs infrared radiation within said silicon dioxide layer.

10. The method of claim 9, prior to said exposing, implanting carbon into said silicon dioxide layer.

11. The method of claim 1, further including:
prior to said exposing, performing an ion implantation into said upper silicon layer of said silicon-on-insulator substrate.

13. The method of claim 11, further including:
prior to said exposing, forming a temperature sensor in said upper silicon layer; and
controlling said beam of infrared radiation in response to a signal from said temperature sensor.

14. The method of claim 1, wherein silicon dioxide has a transmittance of essentially 0% said selected wavelength.

15. The method of claim 1, further including:
selecting said selected wavelength.

16. The method of claim 1, further including:
prior to said exposing, thinning said lower layer of silicon.

17. The method of claim 1, wherein said beam of infrared radiation impinges on said silicon dioxide layer through said lower silicon layer.

18. A structure, comprising:
a buried silicon dioxide layer between a lower layer of silicon and an upper layer of silicon; and
an infrared absorption layer that absorbs infrared radiation within said silicon dioxide layer.

19. The structure of claim 18, wherein said infrared absorption layer comprises carbon.

20. The structure of claim 18, further including field effect or bipolar transistors, portions of which are formed in said upper silicon layer.
